(19) United States
(12) Patent Application Publication
(10) Pub. No.: US 2005/0068041 A1
(43) Pub. Date: Mar. 31, 2005

(54) Evaluation of damage to structures under test using ultrasound

(75) Inventors: Klaus-Peter Kress, Brunnthal (DE); Paul Wolf, Kirchheim (DE)

Correspondence Address: GREENBLUM & BERNSTEIN, P.L.C., 1950 ROLAND CLARKE PLACE, RESTON, VA, 20191, US

(73) Assignee: EADS Deutschland GmbH, Ottobrunn (DE)

(21) Appl. No.: 10/860,047

(22) Filed: Jun. 4, 2004

(30) Foreign Application Priority Data
Jun. 5, 2003 (DE) 103 25 406.4

(51) Int. Cl. G01R 31/08; G01R 31/11

(52) U.S. Cl. 324/527; 324/534

(57) ABSTRACT

The invention concerns nondestructive ultrasonic test equipment for detection and visualization of damage to and in structural components through reflections of introduced ultrasound waves at inhomogeneities in the test area, consisting of primarily piezo sensors, which, depending on how they are driven, can function as transmitter or as receiver for ultrasound waves, and which are permanently attached, for example by gluing, to the damage-critical areas of structural components to be tested and/or monitored, and also of a control device, which is connected to the relevant sensor by electrically conducting wires, so that the received reflected ultrasound waves can be used as imaging data in a suitable device (analysis unit), in order to finally be compared with expected ultrasound images to evaluate any damage that may have occurred. The essence of the invention consists in that the control unit—for example a digital FPGA (field programmable gate array)—is connected to its associated sensor with almost no separation. Another essential inventive concept is to be seen in that the sensors are designed to be two-dimensional or multidimensional such that they can also be used one-dimensionally as needed.

### CROSS-REFERENCE TO RELATED APPLICATIONS

The present application claims priority under 35 U.S.C. § 119 of German Patent Application No. 103 25 406.4 filed Jun. 5, 2003, the disclosure of which is expressly incorporated by reference herein in its entirety.

### BACKGROUND OF THE INVENTION

1. Field of the Invention

The invention relates to the detection of damage up to and including the concrete evaluation of damage to structures, in particular to and in the parts and/or areas thereof that are critical with regard to damage. The detection taking place by nondestructive testing using ultrasound and appropriate sensors, primarily with piezo sensors. In particular, the invention includes nondestructive ultrasonic test equipment for detection and visualization of damage to and in structural components through reflections of introduced ultrasound waves at inhomogeneities in a test area.

2. Discussion of Background Information

Relevant test equipment and methods of this nature are sufficiently known. However, as a general rule, they are associated with unusually large expenditures of money and time, which often escalates their use to the point of unprofitability. The primary reason for this is the generally obstructed accessibility of the sensor system to the critical-regions of a structure. In this context, one need only consider the construction of an airplane, which for inspection in the present context, may under certain circumstances need to be partially or completely removed and disassembled so that the requisite tests can be performed. In this way, a test that itself may require only a few minutes can entail many hours or even several days of preliminary and finishing work. Moreover, in this context it is worthy of mention that the image quality in the visualization of the measurement results suffers to a greater or lesser degree when the sensors cannot be optimally positioned during acquisition of the measurement data, and additionally when the sensors as such do not meet the highest quality standards.

For the aforementioned reasons, it has already been proposed to permanently attach—for example by gluing—the sensors to the locations or areas of a structure to be tested or monitored, and provide them with suitable electrical wires to permit connection with the control unit for the sensors and with the analysis unit for the measurement results in the test equipment. Such a solution is known, for example, since Mar. 8, 2001 from the document “Smart Wide-Area Imaging Sensor System (SWISS), PROC. SPIE, USA, Volume 4332, pages 490-496. This document discloses a nondestructive ultrasound testing method for the detection of damage in a test area of structural components using reflections at inhomogeneities in the test area, wherein multiple piezo ultrasonic sensors are used. These sensors are permanently installed on a structural component in its critical areas, by which means test points are defined in the relevant test area. Ultrasound images are produced from the results of the measurements.

It is further known to store the signals measured with the sensors and compare them with expected values in order to find out whether damage is present as well as the type and extent of such damage.

### SUMMARY OF THE INVENTION

One aspect of the present invention is to improve the entire test concept of the initially mentioned type, both qualitatively and quantitatively.

Up to now, in most cases piezo elements in the form of one-dimensional arrays (rows in matrices) have been and are used as ultrasonic sensors. For example, when such a sensor has 16 rows, it must accordingly be connected to its control unit or analysis unit through 16 individual, separate wires. This is a cumbersome and above all very expensive undertaking when one considers that 50 to 100 sensors are used for measurement or inspection of a high performance aircraft, for example. Disadvantageously, this results in an immense wiring complexity at only comparatively mediocre efficiency of the sensors with only one-dimensional arrays described in detail above.

To improve the efficiency of the sensors, one would have to use them in the form of two-dimensional or even multidimensional arrays, which is technically achievable in principle, but which would cause the wiring complexity to escalate quadratically as compared to the one-dimensional array, namely from 16 to 256 individual connecting wires per sensor.

The invention thus essentially has a specific aspect of making possible the use or employment of one-dimensional, two-dimensional or possibly also multidimensional sensor arrays in test equipment of the type initially mentioned while avoiding the above-mentioned wiring complexity.

This aspect is attained in principle in that particularly the two-dimensional or multidimensional sensor arrays are connected with almost no separation to their fundamentally digital control unit, for example to a digital FPGA (field programmable gate array). The coupling can be accomplished by attached solder balls. Alternatively, it would also be possible within the scope of the invention to implement the connection capacitively through so-called pads on a printed circuit board, for instance. Mechanical finishing and contacting would no longer be necessary in this case. In the event that the piezo elements were to be replaced by thermal ultrasonic transducers (diodes), the necessity for contacting would not apply.

Within the scope of the invention, the sensors coupled in accordance with the invention to their control units are thus permanently attached, for example by gluing, in the damage-critical areas of a structure to be tested or monitored. While this does cause the sensor system to become somewhat heavier as compared to known test systems, this increase in weight is amply compensated for by the fact that complicated wiring between the sensors and their control units is no longer needed in accordance with the invention.

Moreover, the more capable sensor design resulting from the invention permits correspondingly more precise and more reliable measurement results that make it possible to even more closely approach the critical limit in dimensioning the relevant structural parts. Thus, the overall structure can also be reduced in weight still further by this sensor design.

In the field of ultrasonics, the inventive test concept can be designed to be still more efficient for the detection and visualization of the interior condition of a material structure through the use of the phased array method known per se. Material changes resulting, for example, from fatigue or loading beyond the elastic limit, from corrosion at the surface or in bores, etc., or from material inclusions such as foreign bodies, which cause an inhomogeneous material density, can be reliably identified and/or monitored.

In the field of ultrasonics, the phased array method is not yet being used in the economical version according to the invention. In the relevant known methods, it is necessary to work with voltages of approximately 100 volts and more; in the test system according to the invention, in contrast, only voltages of maximum plus/minus 5 volts are required.

The primary advantage of the test equipment according to the invention resides in the miniaturization of the entire sensor system consisting of a multi-element, primarily piezo ultrasonic sensor and a control unit, for example the digital FPGA. The sensor system according to the invention is referred to hereinafter in simplified form as the MiniSWISS sensor (SWISS=smart wide area imaging sensor system).

The basis of the Mini-SWISS sensor is an ultrasound-transmitting and ultrasound-receiving piezo sensor which can function as both transmitter and receiver for the ultrasound under commands from the control unit coupled to the piezo element. The signals received in each case are fed through an ADC (analog-to-digital converter) back to the control unit. The latter can be a “field programmable gate array” (FPGA). The transmitting elements of the sensor system according to the invention are driven directly by the TTL (transistor-transistor logic) outputs of the control unit FPGA. The time base for the system according to the invention can be provided by a quartz oscillator. The necessary delays for driving the outputs and inputs are determined on the basis of the quartz oscillator. It simultaneously provides the reference signal when constructing cascaded systems. The ADC is controlled by the FPGA. Hardware and software programming of the FPGA is performed through a serial interface. An additional bi-directional interface is used for direct data exchange between a PC (personal computer), a microcontroller, etc. and the FPGA. The serial interface can be implemented through a variety of known elements such as, for example, RS232, RS 424, Ethernet, CAN bus, etc. The raw data received are filtered in the FPGA with mathematical algorithms and are prepared for further processing for the visualization of the received signals. The acquired geometric data for the evaluation of damage can then be prepared in the PC for visualization on the monitor. Depending on the application, the representation can take place in 3D, 2D or alphanumeric form.

The test and monitoring system in accordance with the invention has a wide area of application throughout technology. Surfaces of sheet metal and bodies can be scanned even over relatively large distances in that the bodies themselves serve as the transmission medium. Even vibrations of any type such as longitudinal and transverse waves or acoustic emissions, linear expansions, material changes, structural changes with and without reference image, corrosions of any type, and also material inclusions in the form of foreign bodies, which may possibly cause different material densities in the object under test, can be monitored.

The test system in accordance with the invention results from aircraft construction. In its application, however, it is by no means limited to this field. In the broadest sense it can find unlimited application in automotive construction, railroad construction, shipbuilding and machinery manufacture. In machinery manufacture, the following types of problems to be tested and monitored can arise: structural and material tests, material changes, material fatigue resulting from changes in the internal material structure, formation of corrosion of all types, cracking, changes in length due to stretching or compressive strain, deformations, detrimental vibrations, etc.

A very important field of application for the test system in accordance with the invention can emerge for nuclear power plants. Here the invention could also play a pioneering role as online remote monitoring, for example.

Wind power plants and structural engineering in general might also offer a variety of potential applications for the present invention. While the housing and the bearing loads, in particular, must be monitored in wind power plants, the construction industry offers potential applications for the invention with regard to the testing and monitoring of the consistency of building materials, the verification of reinforcement in bridges, especially in their suspension and bedding. Structural members made of concrete, iron and wood offer additional objects for testing and monitoring. Not least, the invention can be helpful in verifying the routing of lines relating to electricity, water and heating, including floor heating.

Furthermore, the system in accordance with the invention is also eminently suitable for mobile use. The system voltage of approximately 5 volts that is typically required can be provided by appropriately suited rechargeable batteries. Hazards to persons operating the system are thus precluded.

Finally, with regard to the many potential applications of the present invention we note the important field of medical technology. The test system in accordance with the invention could for example even be useful here as a substitute for radiography.

Application areas within the scope of medical technology are also conceivable for online observation. All of the possible application areas here include animals as well as humans.

The numerous advantages of the testing and monitoring equipment according to the invention undoubtedly offer many additional potential applications in diverse fields of technology.

Among the advantages of the system in accordance with the invention, the following are particularly worthy of note:
the extremely low drive voltage, which was reduced by a factor of at least twenty as compared to conventional systems;
the input data are prepared in the control unit using mathematical algorithms;
the sensor is divided into rows and columns, with the result that the scan direction can be rotated by 90° by phase control;
as a result of the design of the sensor with rows and columns as a two-dimensional array, a so-called all-around view in the object under test is even made possible by the transition from row activation to column activation; also, instead of rows and/or columns, any desired group divisions or areas of the array can be activated;
direct coupling of the control unit (FPGA) to the two-dimensional or multidimensional sensor array, advantageously by balls on a double-sided printed circuit board. With capacitive coupling, the dielectric can be implemented through the adhesive or through an insulating layer;
The printed circuit board layout constitutes the limit of the geometric resolution. Hence minimal cabling is required. This results in direct driving of the sensor, and also short transit times, high temporal resolution, high immunity to electrical interference, low radiated noise and low susceptibility to interference.
One can also drive the first-mentioned device as a phased array in the conventional sense.
The system can be adapted to the relevant application through reprogramming.
The aperture can be expanded through cascading of Mini-SWISS sensors. The transit time differences can be compensated for in the FPGA, by a uniform time base provided for image generation and geometry matching.
The Mini-SWISS system in accordance with the invention offers a low probability of failure in evaluating objects under test. Objects that are stressed by loads exceeding their elastic limit exhibit fatigue symptoms in their internal material structure. Such changes can be detected numerically, and thus evaluated, with the aid of ultrasound. For example, an aging profile created over time permits a judgment concerning the instantaneous state of the object in general at the site examined.

The present invention is directed to nondestructive ultrasonic test equipment for detection and visualization of damage to and in structural components through reflections of introduced ultrasound waves at inhomogeneities in the test area. The equipment includes sensors, primarily piezo sensors, which, depending on how they are driven, can function as transmitter or receiver for ultrasound waves, and which are permanently attached, for example by gluing, to the damage-critical areas of structural components to be tested and/or monitored. The equipment also includes a control device, which is connected to the relevant sensor by electrically conducting wires, so that the received reflected ultrasound waves can be used as imaging data in a suitable device (analysis unit), in order to finally be compared with expected ultrasound images to evaluate any damage that may have occurred, characterized in that the control unit, for example a digital FPGA (field programmable gate array), is connected to its associated sensor with almost no separation. Moreover, the connection between sensor and control unit can be implemented by gluing by capacitive coupling through so-called pads on a printed circuit board or with a flexible multilayer circuit board. Furthermore, the connection between sensor and control unit can be implemented by a solder connection through so-called solder balls on the pads of a printed circuit board or flexible multilayer circuit board. Additionally, the connection between sensor and control unit can be implemented optically through transmitting and receiving diodes. Furthermore, the connection between sensor and control unit is implemented electromagnetically on a printed circuit board. Moreover, the sensors can be made of piezoceramics or of magnetostrictive or electrostrictive alloys. Additionally, the sensors or the sensor matrix are designed to be two-dimensional or multidimensional such that they can also be used one-dimensionally in a controlled manner. Furthermore, the equipment can include a device for conditioning, e.g. impedance conditioning, of the received ultrasound waves prior to their A/D conversion. Moreover, the equipment can include a device for self-monitoring via self-test, for example with regard to functional testing, calibration, testing for degradation of the sensor material, the adhesive bond and the contacting. Additionally, a positioning precision of the Mini-SWISS sensor can be implemented by a high-precision position sensor, for example by an integral 3D accelerometer that is additionally implemented in the control unit. Moreover, multiple sensor/structure units can be connected together by a network, by which generation and reception of the ultrasound can take place coherently in real time or in synthetic simulation, or manufacturing advantages can additionally be achieved. Additionally, a coherence can be realized in various ways, for example through individual time bases per sensor/control unit or by partially synchronized networks. Furthermore, the transmitting and receiving sequences can be synchronized in a controlled manner, for example through external signals such as in stroboscopic methods. Moreover, an incoherent superposition of the measurement results is also possible, in other words that a summation of the amplitude intensities can be accomplished even without taking phase into account. Furthermore, data relevant to test protocol can be stored in addition to the basic documentation. Additionally, in order to avoid switching the sensors between transmit and receive operation, they are designed within the test equipment with a suitable division to be either only sensors or only actuators. Moreover, the sensors can also be equipped to perform conventional functions such as audio communication (voice transmission and reception, warning signals). Furthermore, the equipment can be equipped to support work processes that depend on precise knowledge of structural condition, as for example surgery, lithotripsy, mobile and/or in-hospital monitoring of patients, robotics in general, welding, and mechanical processing methods. Moreover, the control unit can be equipped to measure parameters relevant to the test, such as temperature, humidity, air pressure, etc. Additionally, the ultrasonic sensor also reacts as a transmitter or receiver to signals even through the instrumented body or the atmosphere.

One aspect of the invention includes a nondestructive ultrasonic tester for detection and visualization of damage to and in structural components through reflections of introduced ultrasound waves at inhomogeneities in a test area. The tester includes a plurality of sensors structured and arranged to at least one of transmit and receive ultrasound waves, the plurality of sensors being attachable to damage-critical areas of structural components to be at least one of tested and monitored. Moreover, the tester includes a controller coupled to at least one of the plurality of sensors with little separation in order to receive reflected ultrasound waves useable as imaging data.

In a further aspect of the invention the imaging data is useable in a device to be compared with expected ultrasound images to evaluate any occurrence of damage. Moreover, the plurality sensors can be piezo sensors. Additionally, the plurality sensors can be structured and arranged for attaching to the structural components by gluing. Furthermore, the controller can be a digital field programmable gate array. Moreover, a coupling between the plurality of sensors and the controller can include a capacitive coupling through one of pads on a printed circuit board and a flexible multilayer circuit board. Additionally, a coupling between the plurality of sensors and the controller can be a solder connection through solder balls on pads of a printed circuit board and a flexible multilayer circuit board. Moreover, a coupling between the plurality of sensors and the controller can include an optical coupling composed of transmitting and receiving diodes. Furthermore, a coupling between the plurality of sensors and the controller can include an electromagnetic coupling. Additionally, the plurality of sensors can be made of one of piezoceramic, magnetostrictive, and electrostrictive alloys. Moreover, the plurality of sensors can be structured and arranged to be one of two-dimensional and multidimensional and controllable to be one-dimensional. The ultrasonic tester can further include a sensor matrix composed of the plurality of sensors structured and arranged to be one of two-dimensional and multidimensional and controllable to be one-dimensional. Moreover, the tester can include a device that conditions received ultrasound waves prior to analog-to-digital conversion. Additionally the device that conditions can be an impedance conditioner. Furthermore, the tester can include a device that self-monitors with a self-test, wherein the device can be configured for at least one of functional testing, calibration, testing for degradation of a sensor material, an adhesive bond testing, and contacting testing. Moreover, at least one of the plurality of sensors can be composed of a Mini-SWISS sensor, and the test can further include an integral 3D accelerometer, arranged in the controller, that implements a positioning precision of the Mini-SWISS sensor. Additionally, the tester can include multiple sensor/structure units connected together by a network, and generation and reception of ultrasound waves can be configured to operate coherently in one of real time and in synthetic simulation. Furthermore, a coherence can be realized through at least one of individual time bases per sensor, individual time bases per controller, and by partially synchronized networks. Furthermore, sequences of transmitting and receiving ultrasound waves can be synchronized in a controlled manner based on stroboscopic method external signals. Moreover, at least one of the plurality of sensors and the controller can be configured to receive an incoherent superposition of measurement results. Furthermore, the controller can store data relevant to test protocol and basic documentation. Additionally, each of the plurality of sensors can be structured and arranged to only one of transmit and receive ultrasound waves. Moreover, the plurality of sensors can be structured and arranged for audio communication. Furthermore, the audio communication can include one of voice transmission, voice reception, and warning signals. Additionally, the tester can be combined with equipment structured and arranged to support work processes that depend on precise knowledge of structural condition, including at least one of surgery, lithotripsy, mobile-hospital monitoring of patients, in-hospital monitoring of patients, robotics, welding, and mechanical processing methods. Moreover, the controller can be structured and arranged to measure parameters relevant to the test including at least one of temperature, humidity, and air pressure. Additionally, the tester can include at least one of a transmitter and a receiver that are structured and arranged to one of transmit and receive signals through at least one of an instrumented body and the atmosphere. Furthermore, the controller can be connected by electrically conducting wires to the at least one of the plurality of sensors.

Another aspect of the invention includes an ultrasonic tester for detection and visualization of damage to and in structural components through reflections of introduced ultrasound waves. The tester includes a plurality of sensors structured and arranged to at least one of transmit and receive ultrasound waves, the plurality of sensors being attachable to areas of structural components to be at least one of tested and monitored. Moreover, the tester includes a controller coupled to at least one of the plurality of sensors in order to receive reflected ultrasound waves useable as imaging data, and a coupling layer structured and arranged to couple the controller to the plurality of sensors.

In a further aspect of the invention the plurality sensors can be piezo sensors. Moreover the controller can be a digital field programmable gate array.

Yet another aspect of the invention includes a vehicle having an ultrasonic tester for detection and visualization of damage to and in structural components through reflections of introduced ultrasound waves. The vehicle including a plurality of sensors that are structured and arranged to at least one of transmit and receive ultrasound waves, the plurality of sensors being attached to at least one structural component to be at least one of tested and monitored. Additionally, the vehicle includes a controller connected to at least one of the plurality of sensors, by electrically conducting wires, and structured and arranged so that received reflected ultrasound waves can be used as imaging data, the controller being arranged and connected to the at least one of the plurality of sensors, and a coupling layer structured and arranged to couple the controller to the plurality of sensors.

In a further aspect of the invention the plurality sensors can be piezo sensors. Moreover, the controller can be a digital field programmable gate array.

Another aspect of the invention includes an ultrasonic test method for detection and visualization of damage to and in structural components through reflections of introduced ultrasound. The method includes coupling a controller to a plurality of sensors through a coupling layer and attaching the plurality of sensors to structural components to be at least one of tested and monitored, the plurality of sensors structured and arranged to at least one of transmit and receive ultrasound waves. Moreover, the method includes receiving, with the plurality of sensors, reflected ultrasound waves as imaging data.

In a further aspect of the invention the plurality sensors can be piezo sensors. Furthermore, the controller can be a digital field programmable gate array.

### BRIEF DESCRIPTION OF THE DRAWINGS

The invention is explained graphically in the figures wherein:

FIG. 1a shows a schematic representation of a Mini-SWISS sensor in accordance with the invention;

FIG. 1b shows a sensor matrix in accordance with FIG. 1a in a two-dimensional design;

FIG. 2 shows a combination of Mini-SWISS sensors in a modular design (six-fold) as a manufacturing proposal; and

FIG. 3a, FIG. 3b, and FIG. 3c show grouped elements of a Mini-SWISS sensor which together approximate a controllably rotatable conventional array.

### DETAILED DESCRIPTION OF THE PRESENT INVENTION

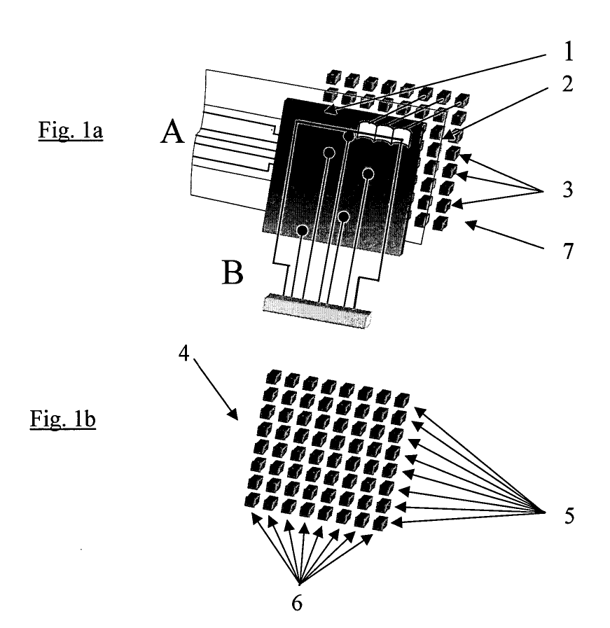

In accordance with FIG. 1a, a microelectronics unit 1 (control unit in the form of, e.g., an FPGA, hybrid, etc.) is connected according to the invention with as little separation as possible through a coupling layer 2 to a sensor matrix 4 consisting of sensor elements 3. In the example shown, the sensor elements 3 consist of piezoelectric material.

FIG. 1b shows a separate view of the sensor matrix 4 from FIG. 1a. In the example shown, the sensor matrix 4 consists of eight rows 5 and a like number of columns 6. The sensor matrix 4 in this case is thus composed of a total of sixty-four sensor elements 3. As a result of the connection (coupling) with as little separation as possible between the microelectronics unit (control unit) 1 and the sensor matrix 4, the invention saves sixty-four more or less long conducting wires per sensor matrix as compared to conventional designs with control units arranged outside the structures under test.

As a result of the invention, the Mini-SWISS sensor module 7 from FIG. 1a, consisting essentially of parts 1 through 3, now has only control, operating and supply lines corresponding to A or B. A variety of possibilities for connecting them exist. Two of them are indicated as alternatives according to the graphical representations A and B in FIG. 1. While the lines are connected between the sensor matrix 4 and the microelectronics unit 1 according to proposal A, the connections of the lines according to B are located on the outside surface of the microelectronics unit 1. In the event that proposal A is implemented, proposal B can be omitted and vice versa.

In the event that these lines should have an interfering effect in the scope of the ultrasonic test equipment in accordance with the invention, they can also be completely, or at least partially to mostly, replaced within the scope of the invention by radio remote controls according to the individual circumstances.

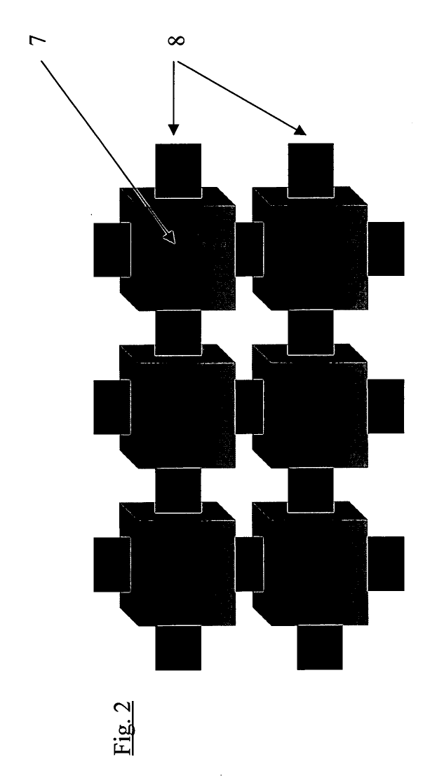

As is clear from FIG. 2, the Mini-SWISS sensor modules 7 in accordance with the invention can be manufactured combined in a matrix form using a common coupling 8, for example in the form of a coupling layer, a flexible polyimide or a copper trace carrier.

Application-specific prefabrication can then be done in each case by cutting out a suitable group of Mini-SWISS sensor modules 7.

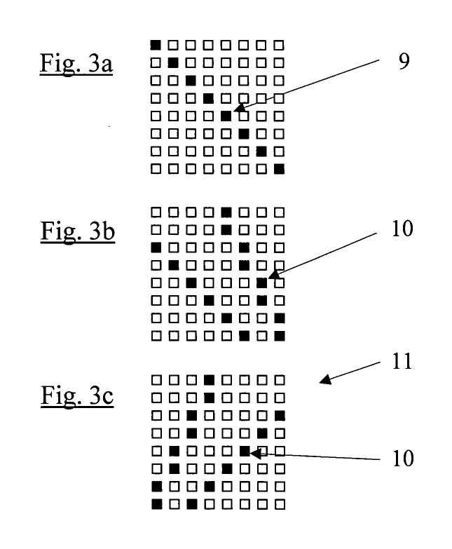

FIGS. 3a through 3c show three possibilities 9, 10 and 11 for program-controlled selection of sensor elements 3 from FIG. 1, each of which are operated for an application-specific use.

Moreover, FIGS. 3b and 3c show how the matrix 10 from FIG. 3b that is chosen here can be rotated by 90° to the right into the setting 11.

1-20. (canceled)

21. A nondestructive ultrasonic tester for detection and visualization of damage to and in structural components through reflections of introduced ultrasound waves at inhomogeneities in a test area, comprising:
a plurality of sensors structured and arranged to at least one of transmit and receive ultrasound waves, the plurality of sensors being attachable to damage-critical areas of structural components to be at least one of tested and monitored; and
a controller coupled to at least one of the plurality of sensors with little separation in order to receive reflected ultrasound waves useable as imaging data.

22. The nondestructive ultrasonic tester according to claim 21, wherein the imaging data is useable in a device to be compared with expected ultrasound images to evaluate any occurrence of damage.

23. The nondestructive ultrasonic tester according to claim 21, wherein the plurality sensors are piezo sensors.

24. The nondestructive ultrasonic tester according to claim 21, wherein the plurality sensors are structured and arranged for attaching to the structural components by gluing.

25. The nondestructive ultrasonic tester according to claim 21, wherein the controller is a digital field programmable gate array.

26. The nondestructive ultrasonic tester according to claim 21, wherein a coupling between the plurality of sensors and the controller comprises a capacitive coupling through one of pads on a printed circuit board and a flexible multilayer circuit board.

27. The nondestructive ultrasonic tester according to claim 21, wherein a coupling between the plurality of sensors and the controller comprises a solder connection through solder balls on pads of a printed circuit board and a flexible multilayer circuit board.

28. The nondestructive ultrasonic tester according to claim 21, wherein a coupling between the plurality of sensors and the controller comprises an optical coupling composed of transmitting and receiving diodes.

29. The nondestructive ultrasonic tester according to claim 21, wherein a coupling between the plurality of sensors and the controller comprises an electromagnetic coupling.

30. The nondestructive ultrasonic tester according to claim 24, wherein the plurality of sensors are made of one of piezoceramic, magnetostrictive, and electrostrictive alloys.

31. The nondestructive ultrasonic tester according to claim 21, wherein the plurality of sensors are structured and arranged to be one of two-dimensional and multidimensional and controllable to be one-dimensional.

32. The nondestructive ultrasonic tester according to claim 21, further comprising:
a sensor matrix composed of the plurality of sensors structured and arranged to be one of two-dimensional and multidimensional and controllable to be one-dimensional.

33. The nondestructive ultrasonic tester according to claim 21, further comprising:
a device that conditions received ultrasound waves prior to analog-to-digital conversion.

34. The nondestructive ultrasonic tester according to claim 21, wherein the device that conditions is an impedance conditioner.

35. The nondestructive ultrasonic tester according to claim 21 further comprising:
a device that self-monitors with a self-test, wherein the device is configured for at least one of functional testing, calibration, testing for degradation of a sensor material, an adhesive bond testing, and contacting testing.

36. The nondestructive ultrasonic tester according claim 21, wherein at least one of the plurality of sensors is composed of a Mini-SWISS sensor, and further comprising:
an integral 3D accelerometer, arranged in the controller, that implements a positioning precision of the Mini-SWISS sensor.

37. The nondestructive ultrasonic tester according to claim 21 further comprising:
multiple sensor/structure units connected together by a network,
wherein generation and reception of ultrasound waves is configured to operate coherently in one of real time and in synthetic simulation.

38. The nondestructive ultrasonic tester in accordance with claim 37, wherein coherence can be realized through at least one of individual time bases per sensor, individual time bases per controller, and by partially synchronized networks.

39. The nondestructive ultrasonic tester according to claim 21, wherein sequences of transmitting and receiving ultrasound waves can be synchronized in a controlled manner based on stroboscopic method external signals.

40. The nondestructive ultrasonic tester according to claim 21, wherein at least one of the plurality of sensors and the controller are configured to receive an incoherent superposition of measurement results.

41. The nondestructive ultrasonic tester according to claim 21, wherein the controller stores data relevant to test protocol and basic documentation.

42. The nondestructive ultrasonic tester according to claim 21, wherein each of the plurality of sensors are structured and arranged to only one of transmit and receive ultrasound waves.

43. The nondestructive ultrasonic tester according to claim 21, wherein the plurality of sensors are structured and arranged for audio communication.

44. The nondestructive ultrasonic tester according to claim 43, wherein the audio communication includes one of voice transmission, voice reception, and warning signals.

45. The nondestructive ultrasonic tester according to claim 21, in combination with equipment structured and arranged to support work processes that depend on precise knowledge of structural condition, including at least one of surgery, lithotripsy, mobile-hospital monitoring of patients, in-hospital monitoring of patients, robotics, welding, and mechanical processing methods.

46. The nondestructive ultrasonic tester according to claim 21, wherein the controller is structured and arranged to measure parameters relevant to the test including at least one of temperature, humidity, and air pressure.

47. The nondestructive ultrasonic tester according to claim 21 further comprising:
at least one of a transmitter and a receiver that are structured and arranged to one of transmit and receive signals through at least one of an instrumented body and the atmosphere.

48. The nondestructive ultrasonic tester according to claim 21, wherein the controller is connected by electrically conducting wires to the at least one of the plurality of sensors.

49. An ultrasonic tester for detection and visualization of damage to and in structural components through reflections of introduced ultrasound waves comprising:
a plurality of sensors structured and arranged to at least one of transmit and receive ultrasound waves, the plurality of sensors being attachable to areas of structural components to be at least one of tested and monitored;
a controller coupled to at least one of the plurality of sensors in order to receive reflected ultrasound waves useable as imaging data; and
a coupling layer structured and arranged to couple the controller to the plurality of sensors.

50. The nondestructive ultrasonic tester according to claim 49, wherein the plurality sensors are piezo sensors.

51. The nondestructive ultrasonic tester according to claim 49, wherein the controller is a digital field programmable gate array.

52. A vehicle having an ultrasonic tester for detection and visualization of damage to and in structural components through reflections of introduced ultrasound waves comprising:
a plurality of sensors that are structured and arranged to at least one of transmit and receive ultrasound waves, the plurality of sensors being attached to at least one structural component to be at least one of tested and monitored;
a controller coupled to at least one of the plurality of sensors, by electrically conducting wires, and structured and arranged so that received reflected ultrasound waves can be used as imaging data, the controller being arranged and connected to the at least one of the plurality of sensors; and
a coupling layer structured and arranged to couple the controller to the plurality of sensors.

53. The vehicle according to claim 52, wherein the plurality sensors are piezo sensors.

54. The vehicle according to claim 52, wherein the controller is a digital field programmable gate array.

55. An ultrasonic test method for detection and visualization of damage to and in structural components through reflections of introduced ultrasound waves comprising:
coupling a controller to a plurality of sensors through a coupling layer;
attaching the plurality of sensors to structural components to be at least one of tested and monitored, the plurality of sensors structured and arranged to at least one of transmit and receive ultrasound waves; and
receiving, with the plurality of sensors, reflected ultrasound waves as imaging data.

56. The method according to claim 55, wherein the plurality sensors are piezo sensors.

57. The method according to claim 55, wherein the controller is a digital field programmable gate array.
